(19) United States
(12) Patent Application Publication
(10) Pub. No.: US 2015/0381160 A1
(43) Pub. Date: Dec. 31, 2015

(54) ROBUST MULTIPLEXER, AND METHOD FOR OPERATING A ROBUST MULTIPLEXER

(71) Applicant: Infineon Technologies AG, Neubiberg (DE)

(72) Inventor: Dieter Draxelmayr, Villach (AT)

(21) Appl. No.: 14/315,500

(22) Filed: Jun. 26, 2014

(51) Int. Cl. H03K 17/16; H01L 29/10; H01L 27/088

(52) U.S. Cl. CPC H03K 17/161; H01L 27/088; H01L 29/1095

(57) ABSTRACT

Multi-channel multiplexers and a method for operating a multi-channel multiplexer are presented, wherein each of a plurality of input channels includes at least one doped bulk well of a conductivity type. The method further includes blocking each input channel of a selection of the plurality of input channels by at least one corresponding control voltage, and bringing each of the at least one doped bulk well of each of the input channels of the selection of the plurality of input channels to an at least one corresponding predetermined voltage. At least one corresponding predetermined voltage is, depending on the conductivity type, either smaller than the corresponding control voltage, or larger than the corresponding control voltage.

### FIELD

The disclosure relates to a multiplexer, and to a method for operating a multiplexer. More particularly, the disclosure relates to an anolog multi-channel multiplexer with pumped bulk wells, and a method for operating such an analog multi-channel multiplexer.

### BACKGROUND

Conventional microcontroller or microprocessor systems—e.g., systems that are used in the automotive field—frequently have to monitor a lot of analog input channels. Typically, a plurality of analog input channels may be digitized by some analog-to-digital converter (ADC). This may be done by feeding a plurality of input channels into a multi-channel multiplexer, where the output of this multiplexer may serve as an input of an ADC.

Typically, analog multi-channel multiplexers comprise an arrangement of (analog) transmission-gate switches. Such transmission-gate switches are typically controlled by a control voltage. The transmission-gate switch may forward an input signal received at an input-channel to its output if the control voltage assumes a first value, typically denoted by V_{DD}. On the other hand, the transmission-gate switch may block an input signal received at an input-channel if the control voltage assumes a second value, typically given by ground, V_{GND}.

Known transmission-gate switches comprise semiconductor devices, typically metal-oxide-semiconductor field-effect transistors (MOSFETs) with different conductivity types, i.e., with either electron (n) doped source and drain regions and a hole (p) doped bulk region (nMOS), or with p-doped source and drain regions and an n-doped bulk region (pMOS).

Because of this, each MOSFET includes two diode (np) structures, that may either be forward-biased if the n-structure lies on a lower potential than the p-structure, or it may be reverse-biased if the n-structure lies on a higher potential than the p-structure. It is known that for an electric current to flow through a forward-biased diode a so-called built-in voltage or diode drop voltage is necessary to be applied to the terminals of the np-structure. It is only under this condition that a diffusion current appearing in proximity of the np-junction can be counterbalanced.

The diode drop voltage depends on several factors, e.g., the doping of the n- and p-structures, current, the semiconductor material and temperature. Typically, the diode drop voltage ranges from 0.4 V to 1.0 V.

When considering an nMOS transistor first, typically the control voltage is applied to the gate terminal of the nMOS transistor while the input line is connected with the drain region (which is equivalent to the source region in this case). The bulk region of the nMOS transistor is also kept at V_{GND}. It might well be that an input voltage is more than one diode drop voltage smaller than V_{GND}. Because of this, the potential of the n-doped drain region is more than a diode drop voltage lower than the potential of the p-doped bulk region. This may, however, lead to a current flow through the nMOS transistor despite a control voltage V_{GND}, indicating the blocking of the nMOS transistor.

Analogous considerations apply if one considers a pMOS transistor comprising p-doped source and drain regions and an n-doped bulk region. Known transmission-gate switches typically include an inverter that inverts the control voltage at the gate terminal of the pMOS transistor with respect to the control voltage at the gate terminal of the nMOS transistor. This means that in the case of a control voltage set to V_{GND}, the gate terminal of the pMOS transistor is set to V_{DD}, and vice versa. It may well be that an input voltage, applied to the source terminal of the pMOS transistor, is more than one diode drop voltage higher than V_{DD}. The bulk region of the pMOS transistor is also kept at V_{DD}. Because of this, the potential of the p-doped drain region is more than a diode drop voltage higher than the potential of the n-doped bulk region. This may lead to a current flow through the pMOS transistor despite a control voltage V_{GND}, indicating the blocking of the entire transmission-gate switch.

Therefore, transmission-gate switches may go to bipolar conduction due to forward-biased source-bulk or drain-bulk diodes when the input voltages either go more than a diode drop voltage below V_{GND}, or when the input voltages exceed V_{DD} by more than a diode drop voltage.

A second effect might lead to weak conduction of a known transmission-gate switch even at input voltages that are less than a diode drop voltage but more than a MOSFET threshold voltage below V_{GND}, or at input voltages that are less than a diode drop voltage, but more than a MOSFET threshold voltage above V_{DD}. The MOSFET threshold voltages may depend on several physical parameters, e.g., the gate material, the thickness of the oxide layer, the conductivity type, doping concentrations of the bulk region, the distance between the source region and the drain region, the temperature and the voltage between source region and bulk region. Typical MOSFET threshold voltages in the case with source and bulk regions at the same potential are a few 100 mV. Already at the before-mentioned MOSFET threshold voltages an n-type (conductive) inversion channel may develop at the semiconductor-oxide interface of the nMOS transistor (thus, the conductivity type is n), and a p-type (conductive) inversion channel may develop at the semiconductor-oxide interface of the pMOS transistor (thus, the conductivity type is p), respectively. Since the inversion channel is of the same type as the source and drain regions, current may pass through it.

The two previously described phenomena are known as parasitic conduction. Parasitic conduction may lead to distortion of an input signal at a multi-channel multiplexer both already at the input channel and/or at the output of the multi-channel multiplexer.

If transmission-gate switches are used in multi-channel multiplexer designs, the selected input signal might be distorted at the output whenever at least one of the input signals corresponds to a voltage that is only a few 100 mV below V_{GND} or a few 100 mV above V_{DD}. Already at such small voltages weak conduction through the inversion channel of a MOSFET might occur. At input voltages that are at least a diode drop voltage below V_{GND} or above V_{DD}, the situation worsens again because of the additional bipolar conduction, e.g., due to the forward-biased source-bulk diode of the nMOS transistor.

However, today, integrated circuit design typically requires very accurate output signals at the multi-channel multiplexer with an error of less than 5 mV, typically between 0.1 mV and 1 mV. This can, however, not be provided by the known transmission-gate switches comprised by known multi-channel multiplexers.

Each channel of a multi-channel multiplexer may comprise a combination of two transmission-gate switches, forming a so-called double-transmission gate, hence comprising two nMOS transistors and two pMOS transistors. In the fabrication process of such double transmission-gate switches each of the two nMOS transistors is implanted on a single p-doped bulk layer, a so-called p-well. Analogously, each of the pMOS transistors is implanted on a single n-doped bulk layer, a so-called n-well.

However, this spatial separation of the single transistors leads to a drastic increase of the area occupied by the multi-channel multiplexer within, e.g., a microcontroller or microprocessor system.

For these or other reasons there is a need for an improved multi-channel multiplexer, and an improved method for operating a multi-channel multiplexer.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and together with the description serve to explain the principles of the disclosure. Other embodiments of the present disclosure and many of the intended advantages of the present disclosure will be readily appreciated, as they become better understood by reference to the following detailed description.

FIG. 1a schematically depicts an analog multi-channel multiplexer feeding one of a selected analog input channels into an analog-to-digital converter (ADC);

FIG. 1b schematically depicts one possible arrangement of transmission gates comprised by an analog multi-channel multiplexer according to an embodiment of the disclosure;

FIG. 2 schematically depicts one possible wiring diagram of a transmission gate as comprised by embodiments of the disclosure;

FIG. 3 schematically depicts a combination of two transmission gates that might be used exemplarily in an analog multi-channel multiplexer according to an alternative embodiment of the disclosure;

FIG. 4a schematically depicts exemplarily two nMOS transistors fabricated on a single p-well as comprised by embodiments of the disclosure;

FIG. 4b schematically depicts exemplarily two pMOS transistors fabricated on a single n-well as comprised by embodiments of the disclosure;

FIG. 5 schematically depicts an analog multi-channel multiplexer according to embodiments of the disclosure feeding one selected of analog input channels into an analog-to-digital converter (ADC).

### DETAILED DESCRIPTION

In the following detailed description, reference is made to the accompanying drawings, which form a part hereof, and in which is shown by way of illustration specific embodiments in which the disclosure may be practiced. It is to be understood that other embodiments may be utilized and structural or other changes may be made without departing from the scope of the present disclosure. The following detailed description, therefore, is not to be taken in a limiting sense, and the scope of the present disclosure is defined by the appended claims.

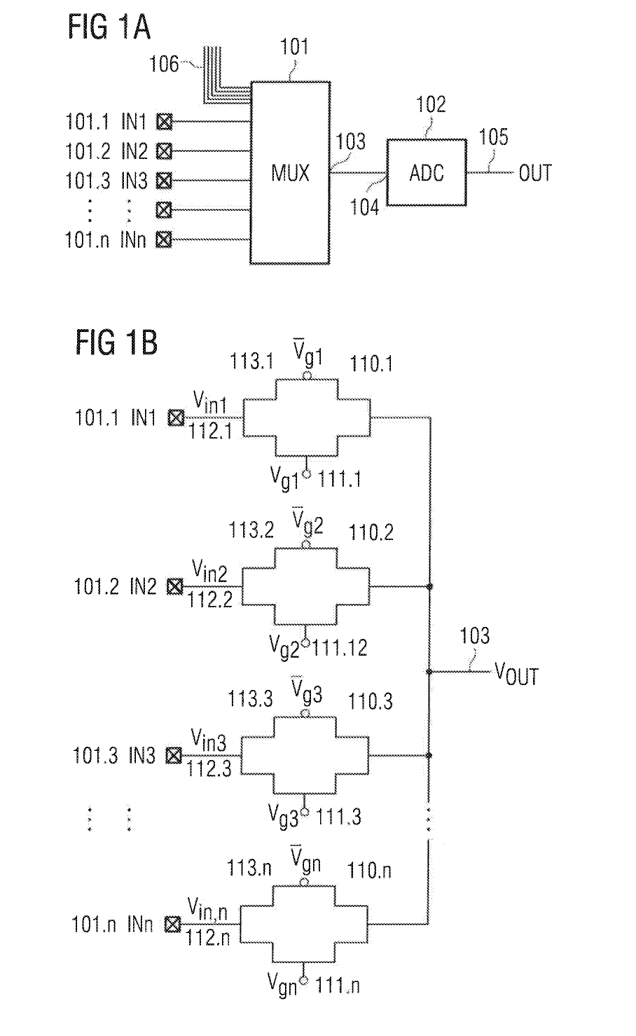

FIG. 1a shows a schematic view of a multi-channel multiplexer (MUX) 101 that is connected to an analog-to-digital converter (ADC) 102. The multiplexer 101 may select one of several signals. In general, the signals might be either analog or digital signals. In the following, analog signals will be considered. In this case, the multiplexer may be a special type of an analog switch comprising so-called transmission gates, described in more detail below in relation to FIG. 1b. The mulitplexer 101 may have n input lines IN1, IN2, IN3, . . . , INn, 101.1, 101.2, 101.3, . . . , 101.n, respectively. In principle, n may be an arbitrary non-negative integer number. Typically, multiplexers that are available as integrated circuits comprise, without being restrictive, between 4 and 32 input lines. From the plurality of input lines 101.1, 101.2, 101.3, . . . , 101.n one might be selected by one or more control signals 106. The selected input line signal is then forwarded to an output 103 of the multi-channel multiplexer 101. In the example case of FIG. 1a, the signal at the output 103 is an analog signal, corresponding to the one selected input signal. This analog signal forwarded to output 103 may then serve as an input signal for the ADC 102. The ADC 102 may convert a continuous analog signal, e.g., a voltage applied at its input 104, to a digital signal OUT 105. This digital signal OUT 105 may, e.g., be processed by a microcontroller or a microprocessor of a machine, for instance, a vehicle, e.g., a car or truck or motorcycle, etc.

FIG. 1b shows schematically an arrangement of transmission gates 110.1, 110.2, 110.3, . . . , 110.n. In complementary metal-oxide-semiconductor (CMOS) technology multi-channel multiplexers comprising transmission gates are called analog multi-channel multiplexers (analog multiplexers). In the case of analog multiplexers, the entire input signal, e.g., input voltage, may be forwarded to an output of the analog multiplexer. This is accomplished by creating a conductive channel between the input and output of the analog multiplexer. Since the conductive channel is not sensitive to the direction of current flow through it, the analog multiplexers might be used at the same time as analog demultiplexers. This means, a signal entering the multiplexer at, e.g., its output 103, that is the demultiplexer's input, might be forwarded to one of the multiplexer's input lines 101.1, 101.2, 101.3, . . . , 101.n, that is, the demultiplexer's output lines.

Each of the transmission gates may be controlled, that is, either blocked or set in conduction state, by applying control voltages V_{g1}, V_{g2}, V_{g3}, V_{gn}, 111.1, 111.2, 111.3, . . . , 111.n, respectively, at the transmission gates 110.1, 110.2, 110.3, . . . , 110.n, respectively. Typically, the control voltages V_{g1}, V_{g2}, V_{g3}, V_{gn}, 111.1, 111.2, 111.3, . . . , 111.n, respectively, are chosen such that only one of the transmission gates 110.1, 110.2, 110.3, . . . , 110.n is conducting while the others are blocked (so-called n-to-1 multiplexers). In such a configuration, only the one selected of the input signals, e.g., of the input voltages Vᵢₙ₁, Vᵢₙ₂, Vᵢₙ₃, . . . , Vᵢₙₙ, 112.1, 112.2, 112.3, . . . , 112.n, respectively, is forwarded to the output 103 of the analog multiplexer. Typically, each of the control voltages V_{g1}, V_{g2}, V_{g3}, V_{gn}, 111.1, 111.2, 111.3, . . . , 111.n, respectively, may assume two values, e.g., the negative supply voltage, V_{SS}, and the positive supply voltage, V_{DD}, introduced further below, e.g., V_{SS}=−3 V to 0 V, for instance, V_{SS}=V_{GND}=0 V and V_{DD}=2 V to 6 V or V_{DD}=6 V to 20 V, e.g., V_{DD}=5 V, V_{DD}=15 V, characterizing the blocking and the conducting, respectively, of each corresponding transmission gate 110.1, 110.2, 110.3, . . . , 110.n.

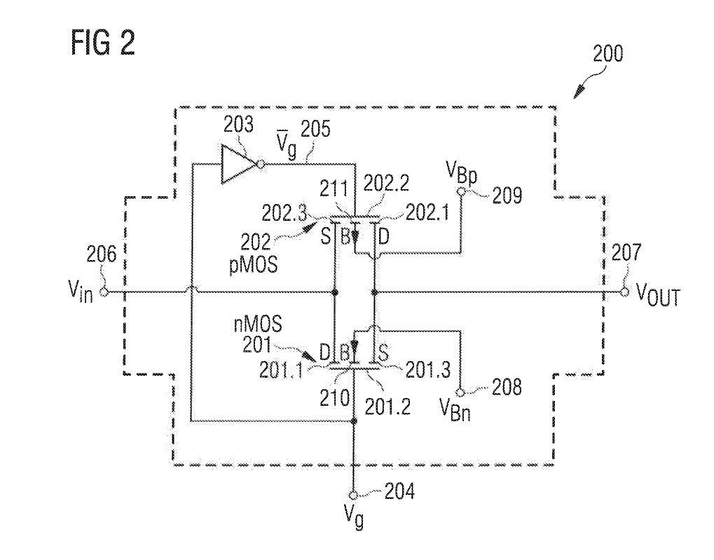

FIG. 2 shows one example schematic wiring diagram of a transmission gate that may be comprised by embodiments of the disclosure, e.g., the arrangement of transmission gates as shown in FIG. 1b. The transmission gate 200 comprises metal-oxide-semiconductor (nMOS) transistors of different conductivity types: an n-channel metal-oxide-semiconductor (nMOS) transistor 201, a p-channel metal-oxide-semiconductor (pMOS) transistor 202 and an inverter 203. In integrated-circuit design, complementary MOS (CMOS) structures might be fabricated, e.g., with the aid of photolithography. Typically, a substrate, e.g., an n-doped or a p-doped semiconductor, may be treated by light-sensitive chemicals and light (e.g., in the ultra-violet wavelength regime) such as to diffuse p-doped or n-doped bulk wells, p-wells or n-wells, respectively, into the substrate. These p-wells or n-wells may then serve as the bulks of, respectively, nMOS transistors or pMOS transistors. In a next step, the n-doped or p-doped source and drain regions may be implanted into the p-wells or n-wells, respectively.

The nMOS transistor 201 comprises a drain terminal 201.1 connected to a first n-doped region that may be fabricated within a p-doped well (p-well), a source terminal 201.3 connected to a second n-doped region that may be fabricated within the p-well, and a gate terminal 201.2. The gate terminal 201.2 might be formed by a metal, e.g., aluminium, but it is not restricted to; nowadays, the gate terminal is often formed by, e.g., a layer of polycrystalline silicon or transition metals. The gate terminal 201.2 may be separated by an oxide, but is not restricted to, since also different dielectric materials may be used, e.g., in particular high-k dielectrics, from a p-doped bulk 210 which may correspond to the p-well. In the example transmission gate 200 the drain terminal 201.1 is connected to an input line 206, e.g., the input voltage Vᵢₙ, the source terminal 201.3 is connected to the output channel 207. The gate terminal 201.2 is connected to the control voltage V_{g} 204. The p-doped bulk 210 which may, for way of example, correspond to or be part of the p-well, is connected to the voltage V_{Bn} 208. The p-doped bulk 210 may be connected with a, e.g., negative supply voltage V_{SS}; in this case V_{Bn}=V_{SS}. It should be noticed, that in this case, source and drain terminals are completely equivalent, that is, current may flow in either direction through the nMOS transistor 201. The pMOS transistor 202 comprises a drain terminal 202.1 connected to a first p-doped region that may be fabricated within an n-doped well (n-well), a source terminal 202.3 connected to a second p-doped region that may be fabricated within the n-doped well, and a gate terminal 202.2. The gate terminal 202.2 might be formed by a metal, e.g., aluminium, but it is not restricted to, or by, e.g., a layer of polycrystalline silicon or transition metals. The gate terminal 202.2 may be separated by an oxide, but is not restricted to, since also different dielectric materials may be used, e.g., in particular high-k dielectrics, from an n-doped bulk 211 which may correspond to the n-well. In the example transmission gate 200 the drain terminal 202.1 is connected to the output channel 207, and to the source terminal 201.3 of the nMOS transistor 201. The source terminal 202.3 is connected to the input line 206, e.g., the input voltage Vᵢₙ, and to the drain terminal 201.1 of the nMOS transistor 201. The gate terminal 202.2 is connected to the control voltage V̅_{g} 205 which corresponds to the control voltage 204 inverted by the inverter 203. That is, if the transmission gate is operative, e.g., at two control voltages V_{c1}, V_{c2}, whereby V_{c1} causes the blocking of the transmission gate 200 (e.g., V_{c1}=V_{SS}) while V_{c2} causes the conducting of the transmission gate 200 (e.g., V_{c2}=V_{DD}), then in the case V_{g}=V_{c1} one obtains V̅_{g}=V_{c2}, while in the case V_{g}=V_{c2} one obtains V̅_{g}=V_{c1}. The n-doped bulk 211 is connected to the voltage V_{Bp} 209. The n-doped bulk 211 may be connected to a, e.g., positive supply voltage V_{DD}; then V_{Bp}=V_{DD}. It might be pointed out, that the negative supply voltage does not necessarily need to be negative, and the positive supply voltage does not necessarily need to be positive. The terminology is meant to underline that the negative supply voltage is smaller than the positive supply voltage.

The functionality of the transmission gate 200 is, thus, amongst others, governed by the functionality of the nMOS transistor 201 and the pMOS transistor 202. The nMOS transistor 201 may become conducting if the voltage V_{g,n} at the gate terminal 201.2 is a typical threshold voltage, U_{th,n}, higher than the voltage V_{S,n} at the source terminal 201.3. Once the gate voltage, V_{g,n}, is a typical threshold voltage, U_{th,n}, higher than the source voltage, V_{S,n}, a so-called (n-conducting) inversion channel may be formed through the p-doped bulk. The threshold voltage may depend on many factors, e.g., the gate material, the thickness of the oxide layer, the conductivity type, the doping concentration of the bulk, the temperature, and the channel length, that is the distance between the two n-doped regions of the source terminal 201.3 and of the drain terminal 201.1. In the case that the bulk voltage, V_{Bn}, is equal to source voltage, V_{S,n}, typical threshold voltages, U_{th,n}, may be a few hundred milli-volts. The bulk voltage, V_{Bn}, does not need to equal the source voltage, V_{S,n}. In the case that V_{Bn}<V_{S,n} the threshold voltage depends on, amongst others, the difference V_{S,n}−V_{Bn}. The effect of such a voltage difference may be explained by considering a backward-biased diode formed by the n-doped source region and the p-doped bulk region. Since the voltage V_{S,n} on the source terminal is higher than the voltage V_{Bn} on the bulk, this diode is backward biased. Because of this, a higher threshold voltage may need to be applied to the gate terminal in order to create an inversion channel. Analogous considerations apply for the pMOS transistor 202. The pMOS transistor 202 may become conducting if the voltage V_{g,p} at the gate terminal 202.2 is a typical threshold voltage, U_{th,p}, lower than the voltage V_{S,p} at the source terminal 202.3. Once the gate voltage, V_{g,p}, is a typical threshold voltage, U_{th,p}, lower than the source voltage, V_{S,p}, a so-called (p-conducting) inversion channel may be formed through the n-doped bulk and current may flow from the source region to the drain region. The threshold voltage may depend on, e.g., the same factors as discussed above in relation to the nMOS transistor 201. In the case that the bulk voltage, V_{Bp}, is equal to source voltage V_{S,p}, typical threshold voltages may be a few hundred milli-volts. For analogous reasons as discussed above with respect to the nMOS transistor 201, in the case of V_{S,p}<V_{Bp}, a higher threshold voltage, may need to be applied to the gate terminal in order to create an inversion channel, that is, the difference V_{S,p}−V_{g,p} may need to be larger in the case V_{S,p}<V_{Bp} as compared to the case V_{S,p}=V_{Bp}.

Finally, it should be noted that it may also be possible to apply a control voltage at the gate terminal 202.2 of the pMOS transistor 202. In this case the inverted voltage is applied at the nMOS transistor 201.

First, the behavior of an ideal transmission gate 200 is described: assume that the control voltage, V_{g}, 204 may assume the two values V_{SS} and V_{DD} of the negative and positive supply voltages that may be connected with the p-bulk 208 and n-bulk 209, respectively. For the mere purpose of example, assume that the control voltage, V_{g}, 204 has a value V_{SS} which might indicate the blocking of the transmission gate 200. In this case, the gate terminal 201.2 and the bulk 210 of the nMOS transistor 201 are at the same potential and no or only a weak inversion channel may develop between the drain region 201.1 and the source region 201.3 of the nMOS transistor 201, regardless of the input voltage, Vᵢₙ, 206. At the same time, the inverter 203 may generate a voltage V̅_{g} 205 which equals V_{DD}. Hence, the gate terminal of the pMOS transistor 202 is at the same potential, namely V_{DD}, as the bulk 211 of the pMOS transistor 202. Therefore, no or only a weak inversion channel might be created, regardless of the input voltage, Vᵢₙ, 206, through the n-doped bulk of the pMOS transistor 202. In the case that the control voltage, V_{g}, 204 is set to V_{DD}, which might be sufficiently higher than V_{SS}, typically V_{DD}=V_{SS}+3 V to V_{SS}+20 V, e.g., V_{DD}=V_{SS}+5 V, V_{DD}=V_{SS}+10 V, then an inversion channel through the nMOS transistor 201 might develop. A current might flow from the drain terminal 201.1 to the source terminal 201.3 of the nMOS transistor 201 as long as the voltage difference VDD−Vᵢₙ is larger than the threshold voltage, U_{th,n}, of the nMOS transistor 201. That means that the nMOS transistor 201 might attenuate or partially block input voltages, Vᵢₙ, 206 higher than V_{DD}−Vᵢₙ although the control voltage, V_{g}, 204 would indicate a forwarding of such voltages. On the other hand, in the case V_{g}=V_{DD}, the voltage at the gate terminal 202.2 of the pMOS transistor 202 equals V̅_{g}=V_{SS}. A p-conducting inversion channel might develop through the pMOS transistor 202 as long as the input voltage Vᵢₙ 206 is a threshold voltage U_{th,p} larger than V_{SS}. In the case of the pMOS transistor 202, input voltages, Vᵢₙ, 206 might be attenuated or partially blocked if they range from V_{SS} to typically V_{SS}+U_{th,p}. Because of this, it is the combination of the nMOS transistor 201 and pMOS transistor 202 comprised by the transmission gate 200 that might guarantee that an input voltage, Vₙ, 206 is forwarded to the output 207 in the case V_{g}=V_{DD}, and that the input voltage, Vᵢₙ, 206 is blocked in the case V_{g}=V_{SS}.

The behavior described previously corresponds to the functioning of an ideal transmission gate 200. The situation might, however, be more involved because of the semiconducting devices comprised in the fabrication of a transmission gate 200. For way of example, an nMOS transistor 201 comprises an np-junction between the source region and the bulk, and it comprises a pn-junction between the bulk and the drain region. Because of this, the nMOS transistor 201 may be thought of an arrangement of two diodes, the one of which is forward-biased, the other is backward-biased. An np-junction may begin conducting when the voltage at the n-region is a typical diode threshold (diode drop) voltage smaller than the voltage at the p-region. In this case, the diode is said to be forward biased. This diode drop voltage may depend on several factors, e.g., the semiconductor material, the conductivity type, the doping concentration of the n- and p-regions, and the temperature. Typical values of the diode drop voltage range from 0.5 V to 1.0 V or from 0.6 V to 0.8 V, and is typically in the ballpark of 0.7 V. An analogous effect may arise within the nMOS transistor 201. It may happen, that the input voltage, Vᵢₙ, 206 falls a typical diode drop voltage below the negative supply voltage, V_{SS}, applied to the bulk 210 of the nMOS transistor 201. As described previously, the nMOS transistor 201 comprises an immanent structure of a bipolar npn-transistor. Therefore, the nMOS transistor 201 not only might become conducting when an n-conducting inversion channel develops, but also when the input voltage, Vᵢₙ, 206 is a diode drop lower than the voltage at the bulk 210. This may imply that the nMOS transistor 201 might become conducting also in cases that exclude such a conduction e.g., when V_{g}=V_{SS}. The bipolar conduction through the immanent npn-transistor comprised by the nMOS transistor 201 is one source of so-called parasitic conduction. Analogous considerations apply to the pMOS transistor 202 that comprises an immanent pnp-transistor. This pnp-transistor might begin conduction when the input voltage, Vᵢₙ, 206 is a diode drop voltage larger than V_{DD}.

In a first embodiment of the present disclosure which is described in the following with regard to FIGS. 1b, 2 and 5, an analog multiplexer comprises n transmission gates 110.1, 110.2, 110.3, . . . , 110.n, which may be, e.g., fabricated according to the wiring diagram of FIG. 2.n may denote an arbitrary integer number; typically n ranges from 4 to 32, but it is not restricted to. Each of the transmission gates may be connected to an input channel IN1, IN2, IN3, INn, 101.1, 101.2, 101.3, . . . , 101.n, respectively. Further, each one of the transmission gates 110.1, 110.2, 110.3, . . . , 110.n may be controlled by corresponding control voltages V_{g1}, V_{g2}, V_{g3}, V_{gn}, 111.1, 111.2, 111.3, . . . , 111.n, respectively. Each of the control voltages, V_{g,j}, may assume at least two values, indicating, respectively, a blocking or a conducting of the transmission gate. It should be noted, by way of example, that all control voltages may be different from each other; or some of them may be equal while the others are different from each other and from the equals one; or all of the control voltages might be equal. Each one of the transmission gates 110.1, 110.2, 110.3, . . . , 110.n may be operative in the ranges from V_{SS,1} to V_{DD,1}, V_{SS,2} to V_{DD,2}, V_{SS,3} to V_{DD,3} and V_{SS,n} to V_{DD,n}, respectively. This means that each of the transmission gates 110.1, 110.2, 110.3, . . . , 110.n might be able to block or forward input signals V_{in,j} (j ranging from 1 to n), 112.1, 112.2, 112.3, . . . , 112.n, each of which ranging from V_{SS,j} to V_{DD,j} depending on the control voltages V_{g,j}=V_{SS,j} or V_{g,j}=V_{DD,j}, respectively.

In the following the blocking of the transmission gates that are comprised by the analog multiplexer according to the first embodiment of the disclosure will be described. Typically, in an n-to-1 analog multiplexer, n-1 transmission gates might be blocked, while only one, say the m-th, transmission gate is conducting. This may, e.g., imply, that n-1 control voltages V_{g,j}=V_{SS,j}, while one, e.g., V_{g,m}=V_{DD,m}. It may well be that V_{SS,j}=V_{SS}, V_{DD,j}=V_{DD} for all j. It is understood that the aforementioned example is not restrictive. An anlog multiplexer according to the first embodiment of the disclosure might also comprise k outputs, where k is, in general, an integer number between 1 and n, with n being the number of input lines of the analog multiplexer. In this general case, n-k transmission gates may be blocked, while k transmission gates are conducting.

As described above, parasitic conduction may arise if the input voltages V_{in,j}, 112.1, 112.2, 112.3, . . . , 112.n lie outside the operation ranges V_{SS,j} to V_{DD,j}, independent of the corresponding control voltages V_{g,j}, 111.1, 111.2, 111.3, . . . , 111.n. Because of this, the voltages V_{Bn,j} and V_{Bp,j} at the bulks of, respectively, the nMOS transistors and pMOS transistors of each of the transmission gates 110.1, 110.2, 110.3, . . . , 110.n may be set, respectively, to a voltage that is at least a diode drop voltage lower or higher than V_{SS,j} or V_{DD,j}. Typically, V_{Bn,j} and V_{Bp,j} may be chosen to be V_{SS,j}−aⱼ·U_{diode}, and V_{DD,j}+aⱼ·U_{diode}, respectively, wherein U_{diode} denotes the diode drop voltage and each of the aⱼ may be any real number typically larger than 1, typically ranging between 0.8 and 2. The values chosen for the aⱼ may depend on several factors, e.g., typical input voltage values V_{in,j} 112.1, 112.2, 112.3, . . . , 112.n, the claimed accuracy of the output signal 103 with respect to an input signal 112.1, 112.2, 112.3, . . . , 112.n. Typically, the aⱼ may, however, be restrained by minimal input voltages, V_{in,j,low}*, or maximal input voltages, V_{in,j,high}*, that are let through the source terminals 202.3 or drain terminals 201.1 by so-called electrostatic discharge (ESD) preventing structures. Such ESD preventing structures prevent voltages that might cause damage or destruction of electronic components or assemblies, e.g., a transmission gate or a multiplexer, from being applied to said components or assemblies. For many purposes it may be the case that there is no distortion of the output signal 103 with respect to an input signal at all; in practice, this might imply that the difference between the voltage at the output 103 with respect to the voltage at a selected input ranges from 10⁻⁹ V to 10⁻³ V, wherein typical input voltages might be of the order of a few volts. It might be, hence, of uttermost importance that no signal, that is, e.g., current or voltage, may pass through each of the blocked transmission gates. If a signal passed through one of the blocked transmission gates, the signal, e.g., current or voltage, of the one selected channel (transmission gate) would be distorted.

The aforementioned voltages typically, V_{Bn,j} and V_{Bp,j} may be properly adjusted with the aid of, e.g., one or more charge pumps 501 as schematically depicted in FIG. 5. The one or more charge pumps 501 may, thus, be connected with the bulk 210, 211 of the nMOS transistor or pMOS transistor, respectively. The charge pump may be included into the wiring diagram of the analog multiplexer. A charge pump may comprise capacitors and switching devices to control the connection of voltages to the capacitor. Charge pumps allow one to, e.g., generate arbitrary voltages, such as one half, one third, 3/2, 4/3, etc. of the original voltage; they further may also allow for an inversion of the original voltage.

So far, only the elimination of the parasitic bipolar conduction has been described. As pointed out before an nMOS transistor 201 may start conducting when the gate terminal 201.2 is at a higher voltage, V_{g,n}, than the source terminal 201.3 (source voltage V_{S,n}). If the voltage difference V_{g,n}−V_{S,n} is larger than a typical threshold voltage, U_{th,n}, the nMOS transistor 201 develops an n-conducting inversion channel, and the input signal may pass through the nMOS transistor 201. It should be noticed, that it is known that the threshold voltage, U_{th,n}, may depend on the difference V_{S,n}−V_{Bn}. Because of this, the necessary threshold voltage may increase with an increasing difference V_{SS}−V_{Bn}. Nevertheless, even at very high differences V_{SS}−V_{Bn}, which might imply large values of the aⱼ, e.g., aⱼ ranging between 1.5 and 2, an input signal 206 may pass through the nMOS transistor 201. This is because the threshold voltages in the case V_{S,n}−V_{Bn}>0 may still be in the ballpark of a few 100 mV. Analogous considerations apply to the pMOS transistor 202 which may start conducting when the gate terminal 202.2 is at a lower voltage, V_{g,p}, than the source terminal 202.3 (source voltage V_{S,p}). If the voltage difference V_{S,p}−V_{g,p} is larger than a typical threshold voltage, the pMOS transistor 202 develops a p-conducting inversion channel, and the input signal may pass through the pMOS transistor 202. It should be noticed, that it is known that the value of the threshold voltage of a pMOS transistor 202 may depend on the difference V_{Bp}−V_{S,p}. Because of this, the necessary threshold voltage may increase with an increasing difference V_{B,p}−V_{DD}. For the same reasons as discussed above in relation to the nMOS transistor 201, even at very high differences V_{Bp}−V_{DD}, which might imply large values of the aⱼ, e.g., aⱼ ranging between 1.5 and 2, an input signal 206 may pass through the pMOS transistor 202.

In each of the transmission gates 110.1, 110.2, 110.3, . . . , 110.n comprised by the analog multiplexer 101 according to the first embodiment of the disclosure each of the gate terminals 201.2 and 202.2 of each of, respectively, the nMOS transistor 201 and pMOS transistor 202 may be connected to one or more charge pumps 501. These charge pumps may be different from the charge pumps connected to the bulk 210 and 211. This allows to set the gate terminals of each of the nMOS transistors 201 and pMOS transistors 202 comprised by the multiplexer 101 to voltages that may be, respectively, lower or higher than extreme input voltages V_{in,j,low}*, V_{in,j,high}*. That is, the extreme input voltages V_{in,j,low}* correspond to the lowest voltages that might arise at the corresponding inputs 101.1, 101.2, 101.3, . . . , 101.n, while the extreme input voltages V_{in,j,high}* correspond to the highest voltages that might arise at the corresponding inputs 101.1, 101.2, 101.3, . . . , 101.n. For way of example, each gate terminal 201.2 of the nMOS transistors 201 or each of the gate terminal 202.2 of the pMOS transistors 202 might be set to a different value. Alternatively, all gates 201.2 of all nMOS transistors 201 may be pumped to the same voltage, e.g., to the lowest of the voltages V_{in,j,low}*, and/or all gates 202.2 of all pMOS transistors 202 may be pumped to the same voltage, e.g., to the highest of the voltages V_{in,j,high}*. In yet another alternative of the first embodiment of the disclosure, the gate terminals of the nMOS transistors 201 and pMOS transistors 202 might be pumped to voltages, e.g., that equal, respectively, V_{Bn,j}, and V_{Bp,j} with the values given above, that is V_{Bn,j}=V_{SS,j}=V_{SS,j}−aⱼ·U_{diode}, V_{Bn,j}=V_{DD,j}+aⱼ·U_{diode}.

To summarize the blocking of the transmission gates 110.1, 110,2, 110.3, . . . , 110.n comprised by the analog multiplexer according to the first embodiment of the disclosure, it should be noticed that adjustment of the voltages at the gate terminals 201.2 of the nMOS transistors 201 and of the voltages at the gate terminals 202.2 of the pMOS transistors 202, e.g, with the use of at least one charge pump, guarantees, amongst others, that no signal passes from the input line through the transmission gate to the corresponding output. The use of a single charge pump may suffice in order to bring the gate and bulk terminals of all blocking transmission gates to a sufficiently low voltage. The value of this voltage may depend on several factors, e.g., the voltages applied at the input lines 112.1, 112.2, 112.3, . . . , 112.n, accuracy of the output signal with respect to the input signal of the selected, i.e., conducting, transmission gate. The transmission gates 110.1, 110,2, 110.3, . . . , 110.n described in relation with the first embodiment of the disclosure may eliminate two sources of parasitic conduction within a transmission gate: the first is, as detailed out above, the bipolar conduction between the source region and drain region through the bulk region, which occurs significantly whenever the voltage at the source is a diode drop voltage lower than the voltage applied at the p-doped bulk of an nMOS transistor, or if the voltage at the source is a diode drop voltage higher than the voltage applied at the n-doped bulk of a pMOS transistor. The second source of parasitic conduction eliminated by the first embodiment of the disclosure is the conduction that may arise if the voltage at the source or drain terminals differs from the voltage at the gate terminal by more than a threshold voltage Uₜₕ which may lead to the creation of a conducting inversion channel through the MOS transistors at the oxide-semiconductor interface.

After the description of the blocking of the transmission gates comprised by the analog multiplexer according to the first embodiment of the disclosure, it is now considered how one or more selected transmission gates can be brought into a conducting state. As describe above a transmission gate begins conduction if the control voltage, V_{g}, 204 is set to a value higher than the control-voltage value indicating the blocking of a transmission gate. For example, V_{g}=V_{DD}, might be chosen. Assume that the gate terminals 201.2 of the nMOS transistors 201 of the conducting transmission gates 110.1, 110.2, 110.3, . . . , 110.n are connected with the control voltages V_{g1}, V_{g2}, V_{g3}, V_{gn}, 111.1, 111.2, 111.3, . . . , 111.n, respectively, then the corresponding gate terminals 201.2 are at the same voltage. Analogously, the gate terminals 202.2 of the pMOS transistors 202 of the conducting transmission gates 110.1, 110.2, 110.3, . . . , 110.n are connected with the control voltages V̅_{g1}, V̅_{g2}, V̅_{g3}, . . . , V̅_{gn}, 113.1, 113.2, 113.3, . . . , 113.n, respectively, then the corresponding gate terminals 202.2 are at the same voltage. It should be noted, that this may be accomplished by an active controlling of the voltage at the gate terminals 201.2 and 202.2. That is, the connection between the gate terminals 201.2 and 202.2 and the at least one charge pump might need to be switched off in the conducting state of the transmission gate, while turned on in the blocking state of the transmission gate. The bulk voltages V_{Bn,j}, V_{Bp,j} may still have the same values as described above in relation to the blocking of the transmission gates, i.e., V_{Bn,j}=V_{SS,j}−aⱼ·U_{diode}, V_{Bp,j}=V_{DD,j}+aⱼ·U_{diode}, etc. This configuration may allow for the forwarding of input voltages V_{in,j} 112.1, 112.2, 112.3, . . . , 112.n that lie within the range of voltages determined by the particular purpose of use, that is, by the chosen values of V_{Bn,j} 208 and V_{Bp,j} 209. Once the gate terminal 201.2 of the nMOS transistor is at a high enough voltage, e.g., V_{g,j}=V_{DD,j}, the nMOS transistor 201 develops an n-conducting inversion channel as long as the difference V_{g,j}−V_{in,j} is larger than the threshold voltage of the nMOS transistor 201. For input voltages that are close to or even higher than the V_{g} indicating conduction, the nMOS transistor 201 blocks. In this case, the gate terminal 202.2 of the pMOS transistor 202 is, however, at a voltage V̅_{g,j}=V_{SS,j}, and the pMOS transistor 202 is then conducting. It should be noticed that V_{g,j}, V_{Bn,j} and V_{Bp,j} might be chosen such as to account for the increase of the threshold voltage with increasing difference V_{S,n,j}−V_{Bn,j} and V_{Bp,j}−V_{S,p,j}.

The analog multiplexer according to the first embodiment of the disclosure leads, thus, to a highly accurate forwarding of the input signal of the selected input line to the output of the analog multiplexer. The distortion of the output signal with respect to the input signal may be reduced to a negligible percentage, i.e., typical relative distortions are smaller than 10⁻²%.

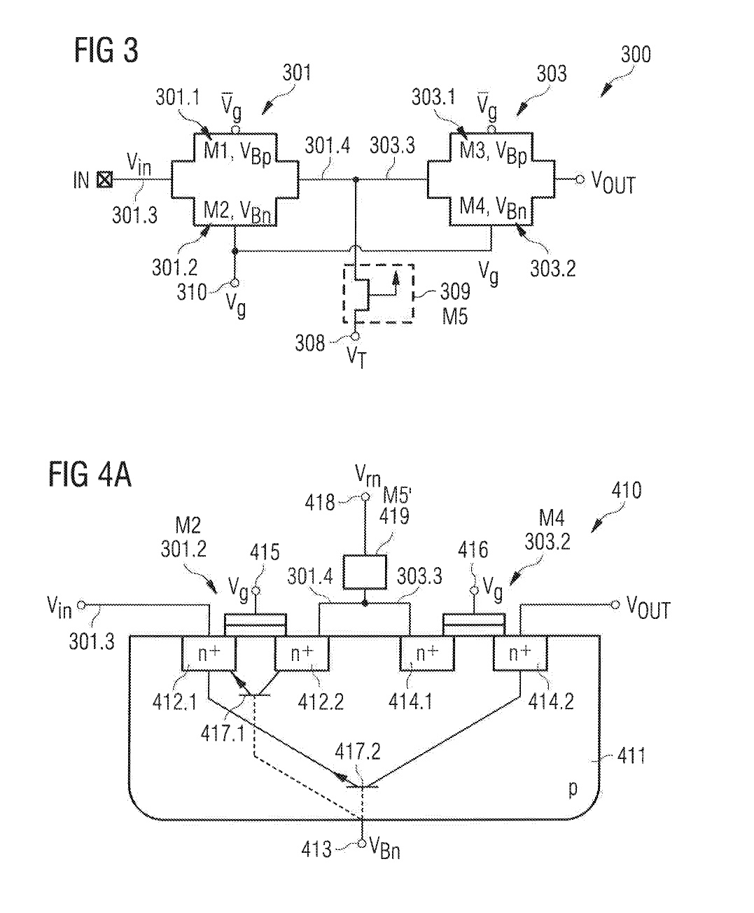

A second embodiment of the disclosure is now described with respect to FIGS. 3, 4a, 4b and 5. According to this embodiment, an analog multiplexer comprises input lines IN1, IN2, IN3, INn, 101.1, 101.2, 101.3, . . . , 101.n, respectively, each of which is connected to a corresponding input 301.3 of a double transmission gate 300. That is, in the case of n input channels 101.1, 101.2, 101.3, . . . , 101.n, where n is a positive integer, and n may, but is not restricted to, typically lie in the range between 4 and 32, the analog multiplexer of the second embodiment may comprise n double transmission gates 300. Each of the double transmission gates 300 may comprise two transmission gates 301, 303, e.g., as described in some detail above in relation with the first embodiment of the disclosure, that are connected in series, that is the output 301.4 of the first transmission gate 301, that might correspond to its drain terminal, may be connected to the input 303.3 of the second transmission gate, that might correspond to its source terminal. This implies, that each of the double transmission gates 300 may comprise, amongst others, two nMOS transistors M2 301.2, M4 303.2, and two pMOS transistors M1 301.1, M3 303.1. Each of the double transmission gates 300 comprised by the analog multiplexer 101 of the second embodiment of the disclosure may be controlled by a control voltage, V_{g,j}, 310 that applies to the gate terminal of the nMOS transistors 301, 303. Exemplarily, in the double transmission gate 300 of FIG. 3 the gate terminals of both nMOS transistors M2 301.2 and M4 303.2 are connected to the same voltage. It may, however, be reasonable to use different control voltages for the gate terminals of the two nMOS transistors M2 301.2 and M4 303.2. As explained above with regard to the first embodiment of the disclosure, the control voltage, V_{g,j}, 310 of each of the double transmission gates 300 may assume two values, e.g., V_{ss,j} and V_{DD,j} which may correspond, respectively, to the negative and the positive supply voltage of the j-th double transmission gate 300 (where j is a positive integer between 1 and n). V_{g,j}=V_{SS,j} then indicates the blocking of the j-th double transmission gate 300, while V_{g,j}=V_{DD,j} indicates the conducting of the j-th double transmission gate 300. The supply voltages V_{SS,j}, V_{DD,j} apply, respectively, to the p-doped bulks of the nMOS transistors M2 301.2, M4 303.2, and the n-doped bulks of the pMOS transistors M1 301.1, M3 303.1. Typically, in an n-to-1 analog multiplexer, n-1 double transmission gates 300 might be blocked, while only one transmission gate 300 is conducting. This may, e.g., imply, that n-1 control voltages V_{g,j}=V_{SS,j}, while one, say, the m-th double transmission gate, e.g., V_{g,m}=V_{DD,m}. It is understood that the aforementioned example is not restrictive. An anlog multiplexer according to the second embodiment of the disclosure might also comprise k outputs, where k is, in general, an integer number between 1 and n, with n being the number of input lines of the analog multiplexer. In this general case, n-k double transmission gates may be blocked, while k double transmission gates are conducting. Furthermore, it is not necessary for all V_{SS,j} and/or V_{DD,j} being different from each other. In another alternative, all V_{SS,j} may be equal, and all V_{DD,j} may be equal; or some of the V_{SS,j} may be equal while others are different from one another; similarly, some of the V_{DD,j} may be equal while others are different from one another.

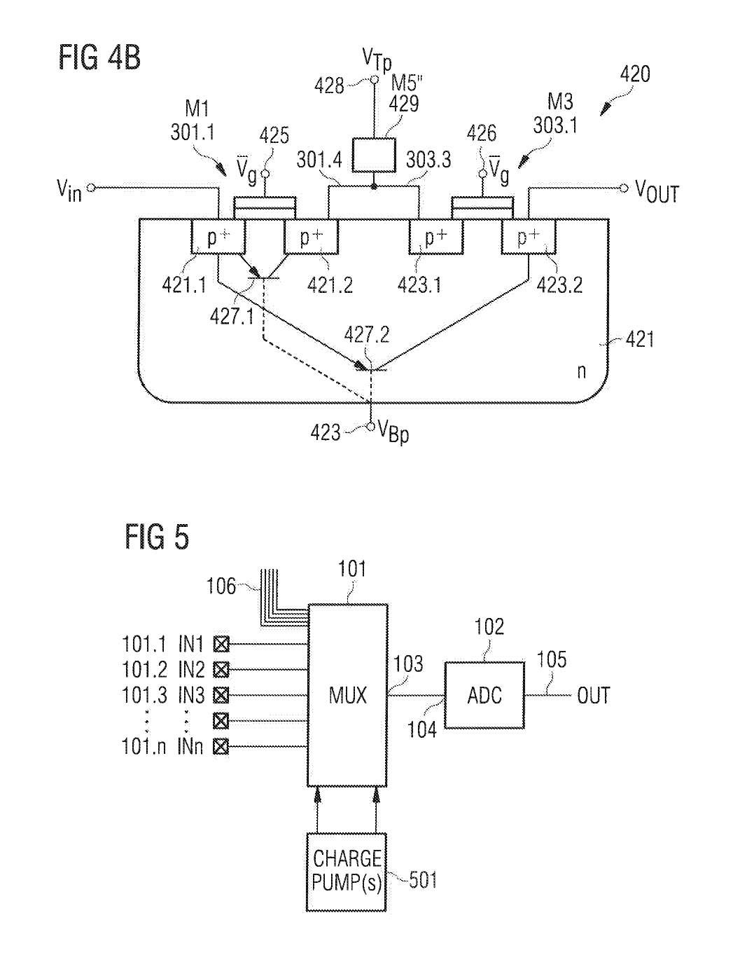

The physical layout of the nMOS structure 410 comprising the nMOS transistors M2 301.2, M4 303.2 comprised by the double transmission gate 300 is shown in FIG. 4a, the physical layout of the pMOS structure 420 comprising the pMOS transistors M1 301.1, M3 303.3 is shown in FIG. 4b. The whole double transmission gate 300 may be fabricated, e.g., by means of photolithography as described above. For the double-transmission-gate structure an n-doped or a p-doped substrate may be used. In the case of an n-doped substrate, the pMOS transistors M1 301.1 and M3 303.1 are formed by diffusing the p-doped source regions 421.1, 423.1 and drain regions 421.2, 423.2 into the n-doped substrate 421. The corresponding nMOS transistors M2 301.2 and M4 303.2 are comprised by the p-well 411 that may be diffused into the n-substrate for forming the bulk of one or more nMOS transistors. As shown in FIG. 4a, it is then desirable, but not limiting, to implant, e.g., all n-doped drain regions 412.1, 414.1, and source regions 412.2, 414.2 that correspond to one double transmission gate in one single p-well. In an alternative of the second embodiment of the disclosure, the n-doped drain regions and source regions of all double transmission gates comprised by the analog multiplexer 101 might be implanted in a single or limited number of p-wells. In a further alternative of the second embodiment of the disclosure, the source region 412.2 and the drain region 414.1 might be comprised by a single n-doped region. This reduces the area of the nMOS structure 410 further.

Analogous considerations apply to the case where a p-doped substrate is used: one or more n-wells are diffused into the p-doped substrate for forming the bulks of the pMOS transistors M1 301.1, M3 303.1 of each of the double transmission gates comprised by the analog multiplexer 101. It is then desirable, but not limiting, to implant, e.g., all p-doped source regions 421.1, 423.1, and drain regions 421.2, 423.2 that correspond to one double transmission gate in one single n-well. As described above, the p-doped source regions and drain regions of all double transmission gates comprised by the analog multiplexer 101 might be implanted in a single or limited number of n-wells. In this second example, the n-doped drain regions 412.1, 414.1, and source regions 412.2, 414.2, of the nMOS transistors M2 301.2, M4 303.2 of the double transmission gates comprised by the analog multiplexer 101 of the second embodiment of the disclosure, may be implanted in the p-doped substrate. In a further alternative of the second embodiment of the disclosure, the source region 421.2 and the drain region 423.1 might be comprised by a single p-doped region. This reduces the area of the pMOS structure 420 further.

In a further alternative of the second embodiment of the disclosure a so-called triple-well structure may be used: in this case, one or more n-wells 421 may be first diffused into a p-substrate. The n-well(s) 421 form the bulk(s) of pMOS transistors. Next, one or more p-wells 411 may be diffused into (each of) the n-well(s). The p-well(s) 411 form the bulk(s) of nMOS transistors. The pMOS transistors M1 301.1 and M3 303.1 are formed by diffusing the p-doped source regions 421.1, 423.1 and drain regions 421.2, 423.2 into the n-well(s) 421. The corresponding nMOS transistors M2 301.2 and M4 303.2 are comprised by the p-well(s) 411 diffused into the n-well(s). As shown in FIG. 4a, all n-doped drain regions 412.1, 414.1, and source regions 412.2, 414.2 that correspond to one double transmission gate may be implanted in one single p-well. It may, however, be preferable to implant the n-doped drain regions and source regions of all double transmission gates comprised by the analog multiplexer 101 in a single or limited number of p-wells. One advantage of the triple-well structure is that only the wells need to be pumped. It might not be necessary to pump the substrate. Finally, the source region 412.2 and the drain region 414.1 might be comprised by a single n-doped region. This reduces the area of the nMOS structure 410 further.

A triple-well structure might analogously be formed by using an n-doped substrate comprising one or more p-wells each of which comprises one ore more n-wells. The p-well(s) form the bulk of one or more nMOS structures. The n-wells form the bulk of one or more pMOS structures.

In the following, the nMOS structure 410 of the analog multiplexer 101 of the second embodiment of the disclosure is first described. The one or more p-wells comprise at least two nMOS structures M2 301.2, M3 303.2. As pointed out before, in one alternative it may be desirable to implant more than two or all nMOS structures comprised by the analog multiplexer 101 in a single p-well. Each of the gate terminals, that is the metal-oxide structure, 415, 416 may be fabricated as described above in relation with the first embodiment of the disclosure.

Now, the blocking of one example double transmission gate 300 according to the second embodiment of the disclosure is described. In this case the gate terminals 415, 416, of each double transmission gate 300 that needs to be blocked may be set to the corresponding control voltage V_{g,j}, e.g., V_{g,j}=V_{SS,j}, or V_{g,j}=V_{SS} if all negative supply voltages are the same. The p-well or the p-wells 411 are set to a voltage V_{Bn,j} 413 that is at least a diode drop voltage U_{diode} lower than V_{SS,j}, typically V_{Bn,j}=V_{SS,j}−aⱼ ·U_{diode}, wherein U_{diode} denotes the diode drop voltage and each of the aⱼ may be any real number typically ranging between 0.8 and 2. The values chosen for the aⱼ may depend on several factors, e.g., typical minimal input voltages, V_{in,j,low}*, or maximal input voltages, V_{in,j,high}*, determined by the ESD preventing structures, the claimed accuracy of the output signal 103 with respect to an input signal 112.1, 112.2, 112.3, . . . , 112.n. For many purposes the case may be that there is no distortion of the output signal 103 with respect to an input signal at all; in practice, this might imply that the relative error between the voltage at the output 103 and the voltage at a selected input is smaller than 10⁻²%. It might, hence, be of uttermost importance that no signal, that is, e.g., current or voltage, may pass through each of the blocked double transmission gates. If a signal passed through one of the blocked double transmission gates, the signal, e.g., current or voltage, of the one selected channel (double transmission gate) would be distorted. Therefore, by setting the voltages V_{Bn,j} 413 of the p-well or p-wells properly, the parasitic bipolar conduction can be eliminated. It should be noticed that, since the nMOS structure 410 comprises more than one npn transistor structures, e.g., the npn transistor 417.1 comprising the n-doped drain region 412.1, the n-doped source region 412.2 and the p-well itself, or the npn transistor 417.2 comprising the n-doped drain region 412.1, the n-doped source region 414.2 and the p-well itself. Thus, by applying a properly chosen bulk voltage V_{Bn,j} 413, all possible sources for parasitic bipolar conduction are eliminated or highly suppressed. One possibility of how to properly choose the bulk voltages V_{Bn,j} 413 will be presented in the following paragraph.

The p-doped substrate or the p-well(s) 411 of the nMOS structure 410 may be connected to one or more charge pumps 501, whereby a typical charge pump has already been described above in relation to the first embodiment of the disclosure, and will, thus, be referred to without being repeated here again. This allows to set the p-doped substrate or the p-well(s) 411 of the nMOS structures 410 comprised by the multiplexer 101 to voltages that may be lower than extreme input voltages V_{in,j,low}*. That is, the extreme input voltages V_{in,j,low}* correspond to the lowest voltages that might arise at the corresponding inputs 101.1, 101.2, 101.3, . . . , 101.n, e.g., voltages allowed for by the ESD preventing structures. For way of example, if present, each p-well of the nMOS structures 411 might be set to a different value. Alternatively, all p-wells (if more than one is present) 411 of all nMOS structures 410 may be pumped to the same voltage, e.g., to the lowest of the voltages V_{in,j,low}*. It should be noted that the values aⱼ given above, might be related to the corresponding V_{in,j,low}*, that is, e.g., through V_{Bn,j}==V_{SS,j}−aⱼ·U_{diode}.

As explained already above in relation to the first embodiment of the disclosure, there may exist a second source of parasitic conduction. Once the p-doped substrate or the p-well(s) 411 lies at a lower potential than the gate terminal 415, depending on the voltage V_{in,j} at the input line 301.3 an n-conducting inversion channel might develop. Such an inversion channel may develop when the input voltage, V_{in,j}, applied at the drain terminal 412.1 of the nMOS structure 410 is a threshold voltage, U_{th,n,j}, lower than the voltage at the gate, V_{g,j}, 310. As pointed out above in relation with the first embodiment of the disclosure, the threshold voltage may depend on many factors, e.g., the gate material, the thickness of the oxide layer, the conductivity type, the doping concentration of the p-well or the bulk, the temperature, and the channel length, that is the distance between the two n-doped regions of the source terminal 412.2 and of the drain terminal 412.1; further, it is known that the threshold voltage may scale as a function of the difference V_{in,j}−V_{Bn,j}. Because of this, the necessary threshold voltage may increase with an increasing difference V_{SS,j}−V_{Bn,j}. Nevertheless, even at very high differences V_{SS,j}−V_{Bn,j}, which might imply large values of the aⱼ, e.g., aⱼ ranging between 1.5 and 2, an input signal may pass through the nMOS transistor M2 301.2. This is because the threshold voltages in the case V_{in,j}−V_{Bn,j}>0 may still be in the ballpark of a few 100 mV. The signal 301.4 at the output of the nMOS transistor M2 301.2 may be, e.g., an attenuated or distorted input signal V_{in,j}. According to the second embodiment of the disclosure, the output signal 301.4 of the nMOS transistor M2 301.2 might be brought to a voltage V_{T,j} 308 that makes sure that the nMOS transistor M4 303.2 blocks. For this, V_{T,j} 308 may be equal to or higher than the control voltage, V_{g,j}, indicating the blocking of the double transmission gate, e.g., V_{T,j}=V_{SS,j} or V_{T,j}>V_{SS,j}. In one example of the present embodiment, it may be sufficient to choose one single V_{T,j} 308 for all double transmission gates, e.g., V_{T}=V_{T,j}=V_{SS,j}+ε=V_{SS}+ε, wherein ε may be a small positive real number, typically, e.g., ε equals a few 100 mV. In another alternative, εⱼ=(V_{DD,j}−V_{SS,j})/2, which sets V_{T} to the middle between V_{DD,j} and V_{SS;j}. The values chosen for the V_{T,j} 308 may depend on several factors, e.g., the control voltages V_{g,j} indicating the blocking of the nMOS transistors, the claimed accuracy of the output signal 103 with respect to an input signal 112.1, 112.2, 112.3, . . . , 112.n. For the purpose of adjusting the voltage at the input 303.3 of the nMOS transistor M4 303.2 a transistor 419 might be used. It may be activated, that is, be set into the conduction direction, when the control voltage, V_{g,j}, indicates a blocking of the double transmission gate. The transistor 419 serves as a variable resistor: in the case that V_{g,j} indicates the blocking of the double transmission gate 300, a corresponding base voltage is applied to the transistor which implies that the transistor acts as a low-ohmic resistor (with a resistance that may typically be a few Ohms to kilo-Ohms). Therefore, the input 303.3 to the second transmission gate 303 substantially lies at the potential V_{T,j} 308 which is applied to one terminal of the transistor 419. The voltage difference that drops off at the transistor 419 may be corrected for by choosing the e introduced above accordingly. In this case, the current that is passed through the nMOS transistor M2 301.2 may flow off the transistor 419. By the use of, e.g., a transistor M5 309, to set the voltage at the input 303.3 of the nMOS M4 303.2 to a predetermined value, the nMOS transistor M4 303.2 is blocking. The transistor M5 309 may be used as a controllable switch; when this switch is closed, the connection line between the output 301.4 of the first transmission gate and the input 303.3 of the second transmission gate is at the potential V_{T,j} 308, when the switch is open, the output signal 301.4 is unalteredly passed to the input 303.3. Because of V_{T,j}=V_{g,j} or V_{T,j}>V_{g,j}, wherein V_{g,j} indicates the blocking control voltage, the drain region 414.1 is at an equal potential as or at a higher potential than the gate voltage V_{g,j}, and therefore no inversion channel might be created, and, hence, no signal, e.g., voltage or current, is forwarded to the source 414.2 of the nMOS transistor M4 303.2.

Turning now to the pMOS structures 420, analogous considerations apply as for the nMOS structure 410. The pMOS structures 420 may be implanted into the n-doped substrate that may comprise the n-well(s) and corresponding nMOS structures 410 as described above, or the pMOS structures 420 may comprise one or more n-wells 421 that are diffused into a substrate. The source regions 421.1, 423.1 and drain regions 421.2 and 423.2 of the pMOS transistors M1 301.1 and M3 303.1 may, thus, be implanted in the n-doped substrate or in the one or more n-wells.

In the case that the control voltage, V_{g,j}, is chosen such as to indicate the blocking of the double transmission gate 300, e.g., V_{g,j}=V_{SS,j}, the gate terminals 425, 426, of the pMOS transistors M1 301.1 and M3 303.1 are set, by means of an inverter comprised by the double transmission gate, to corresponding voltages V̅_{g,j}, e.g., if V_{g,j}=V_{SS,j}, then V̅_{g,j}=V_{DD,j}. The n-doped substrate or the n-well(s) 421 are set to a voltage(s) V_{Bp,j} 423 that is (are) at least a diode drop voltage U_{diode} higher than the, e.g., maximal, value of V_{DD,j}, typically V_{BP,j}=V_{DD,j}+aⱼ·U_{diode}. The values aⱼ may be the same as described above in relation to the nMOS structure 410, or the aⱼ might be differently chosen, e.g., based on the factors given above. By setting the voltage(s) V_{Bp,j} 423 of the n-doped substrate or the n-well(s) properly, the parasitic bipolar conduction may be eliminated. If the n-doped substrate or the n-well(s) 421 are set to voltages that may be higher than extreme input voltages V_{in,j,high}*, wherein the extreme input voltages V_{in,j,high}* correspond to the highest voltages that might arise at the corresponding inputs 101.1, 101.2, 101.3, . . . , 101.n, e.g., because of the ESD preventing structures, then the n-doped substrate or the n-well(s) 421 are always on a higher voltage than the source region 421.1 of the pMOS transistor M1 301.1. Because of this, not only is the parasitic bipolar conduction eliminated or highly suppressed through the immanent pnp transistor 427.1 comprising the source region 421.1, the drain region 421.2 and the substrate or p-well 421, but also, e.g., through the immanent pnp transistor 427.1, comprising the source region 421.1, the drain region 423.2 and the substrate or p-well 421. For way of example, if present, each n-well of the pMOS structures 421 might be set to a different value. Alternatively, all n-wells (if more than one is present) 421 of all pMOS structures 420 may be brought to the same voltage, e.g., to the highest of the voltages V_{in,j,high}*.

The n-doped substrate or the n-well(s) 421 of the pMOS structure 420 may be connected to one or more charge pumps 501, whereby a typical charge pump has already been described above in relation to the first embodiment of the disclosure, and will, thus, be referred to without being repeated here again. This allows to set the n-well(s) 421 of the pMOS structures 420 comprised by the multiplexer 101 to voltages that may be higher than extreme input voltages V_{in,j,high}*. For way of example, if present, each n-well of the pMOS structures 421 might be set to a different value. Alternatively, all n-wells (if more than one is present) 421 of all pMOS structures 420 may be pumped to the same voltage, e.g., to the highest of the voltages V_{in,j,high}*. It should be noted that the values aⱼ given above, might be related to the corresponding V_{in,j,high}*, that is, e.g., through V_{Bp,j}==V_{DD,j}+aⱼ·U_{diode}.

As explained above in relation to the nMOS structure 410, there may exist a second source of parasitic conduction. Once the n-doped substrate or the n-well(s) 421 lie at a higher potential than the gate terminal 425, depending on the voltage at the input line 301.3 a p-conducting inversion channel might develop through the pMOS transistor M1 301.1. Such an inversion channel may develop when the input voltage Vin,j applied at the source terminal 421.1 of the pMOS transistor M1 301.1 is a threshold voltage, U_{th,p,j}, higher than the voltage at the gate, V_{g,j}, 425. The threshold voltage, U_{th,p,j}, may depend on the factors given above in relation to the nMOS structure 410; further, it is known that the threshold voltage may scale as a function of the difference V_{Bp,j}−V_{in,j}. Because of this, the necessary threshold voltage, U_{th,p,j}, may increase with an increasing difference V_{Bp,j}−_{DD,j}. Nevertheless, even at very high differences V_{Bp,j}−V_{DD,j}, which might imply large values of the aⱼ, e.g., aⱼ ranging between 1.5 and 2, an input signal may pass through the pMOS transistor M1 301.1. This is because the threshold voltages in the case V_{Bp,j}−V_{in,j}>0 may still be in the ballpark of a few 100 mV. The signal 301.4 at the output of the pMOS transistor M1 301.1 may be, e.g., an attenuated or distorted input signal Vin,j.

According to the second embodiment of the disclosure, a transistor M5 309 may be connected to the connection between the first transmission gate 301 and second transmission gate 303. As detailed out above in relation to the nMOS structure 410, a transistor M5″ 429 may serve as a switch or variable resistance. It should be noticed, that one transistor might be sufficient, that is, M5′ 419 is the same as M5″ 429. In the case that the control voltage, V_{g,j}, indicates a blocking of the double transmission gate 300, e.g., V_{g,j}=V_{SS,j}, than the transistor becomes very low-ohmic (resistance of typically a few Ohms to kilo-Ohms) and brings the connection between the output 301.4 of the first transmission gate and the input 303.3 of the second transmission gate to the voltage V_{T,j} 308 described above with respect to the nMOS structure 410. As long as V_{T,j} is 308 chosen in the range from V_{SS}+ε to V_{DD}−ε (ε as indicated above), the pMOS structure 420 may not develop a p-conducting inversion channel, because the gate terminal 426 is, in the case of the blocking, at a voltage V̅_{g}=V_{DD}, while the source terminal 423.1 of the pMOS transistor M3 303.1 is at the lower potential V_{T,j} 308. So far, a single transistor M5=M5′=M5″ has been described. It should be noticed, that it might also be possible to choose different transistors M5′ 419 and M5″ 429 for the nMOS structures 410 and pMOS structures 420. In such a case it may be sensible to only connect the n-doped regions 412.2 and 414.1 through one connection 301.4, 303.3, on one hand, and to separately connect the p-doped regions 421.2 and 423.1 through another connection 301.4, 303.3, on the other. By doing so, the transistor M5′ 419 might block the signal that passes through the nMOS transistor M2 301.2, and the transistor M5″ 429 might block the signal that passes through the pMOS transistor M1 301.1, in the case that the control voltage V_{g,j} indicates a blocking of the double transmission gate. In this alternative, one terminal of the transistor M5 is connected to a potential V_{Tn,j} 418 that is higher than the control voltage, V_{g,j}, indicating blocking, e.g., V_{Tn,j}>V_{SS,j}, and M5′ is connected to a potential V_{Tp,j} 428 that is lower than the voltage V̅_{g,j} indicating blocking, e.g., V_{Tp,j}<V_{DD,j}. The transistors M5 419 and M5′ 429 might then become low-ohmic by applying a corresponding gate voltage whenever the control voltage, V_{g,j}, indicates a blocking of the double transmission gate 300.

To summarize the blocking of the double transmission gate 300 according to the second embodiment of the disclosure, the use of, e.g., at least one charge pump to bring the p-well(s) 411 of an nMOS structure 410 to a potential that is at least a diode drop voltage lower than the negative supply voltages, V_{SS,j}, and to bring the n-doped substrate or the n-well(s) 421 of the pMOS structure 420 to a potential that is at least a diode drop voltage higher than the positive supply voltage, V_{DD,j}, in addition to transistors 309 that may adjust the potential at the input line 303.3 of the second transmission gate 303, may eliminate both unwanted bipolar conduction due to the immanent bipolar transistor structures 417.1, 417.2, 427.1 and 427.2, and the weak conduction due to the creation of conducting inversion channels through the MOS structures.

Now, the conduction of the double transmission gate 300 is described. In this case, the transistor M5 309 or the transistors M5′ 419 and M5″ 429 are switched off, that is, the transistors M5 309, M5′ 419 and M5″ 429 are extremely high-ohmic (resistances of typically, e.g., a several giga-Ohms) such that the output signal 301.4 of the first transmission gate 301 is unalteredly passed to the input 303.3 of the second transmission gate 303. The conduction of the double transmission gate is indicated by a corresponding control voltage, V_{g,j}, e.g., V_{g,j}=V_{DD,j}; in some alternatives of the second embodiment of the disclosure it may be desirable to choose all V_{g,j} equal, e.g., V_{g}=V_{g,j}=V_{DD,j}=V_{DD}. Consequently, the gate terminals 415 and 416 of the nMOS transistors M2 301.2 and M4 303.2 may then also be at the potential V_{g,j}, and the gate terminals 425 and 426 of the pMOS transistors M1 301.1 and M3 303.1 may be at the potential V̅_{g,j}, e.g., V̅_{g,j}=V_{SS,j}. As described above in relation to the first embodiment of the disclosure, input voltages, V_{in,j}, that are higher than V_{SS,j}, but still close to V_{SS,j}, are passed through the n-conducting inversion channel of the first nMOS transistor M2 301.2 due to the positive voltage difference V_{g,j}−V_{in,j}. The closer V_{in,j} comes to V_{DD,j}, the more of the input signal V_{in,j} passes through the p-conducting inversion channel of the pMOS transistor M1 301.1, because of the increasing difference V_{in,j}− V̅_{g,j}. The combination of the nMOS transistor M2 301.2 and the pMOS transistor M1 301.1 guarantees that an input signal V_{in,j} is passed through the transmission gate 301 without being distorted or attenuated. Further aspects of the forwarding a of signal through the transmission gate 301 are described above in relation to the first embodiment of the disclosure, these explanations are referenced here without being repeated. Because of the high-ohmic transistor(s) M5, M5 and M5′, respectively, the output signal 301.4 is unalteredly passed to the input 303.3 of the second transmission gate 303. Therefore, the same reasoning as described in relation to the forwarding of a signal through the first transmission gate 301 applies here, as well. Eventually, the input signal, is unalteredly forwarded through the entire double transmission gate 300 whenever a control voltage is applied that indicates the conduction of the double transmission gate.

The analog multiplexer according to the second embodiment of the disclosure may, in one embodiment, comprise a plurality of n of the above-described double transmission gates 300, e.g., implanted on a single substrate, as outlined above, one or more charge pumps 501, and at least n transistors that might be laid out on the same or a different substrate. According to the second embodiment of the disclosure it is possible to implant the transmission gates comprised by the double transmission gates of the analog multiplexer on a single p- or n-doped well. Because of this, the multiplexer extends over a significantly smaller area as it would, if each MOS structure were implanted in an individual well. Therefore, it is possible to achieve smaller structures, e.g., in microcontroller and/or microchip design. This is accomplished by bringing the well(s) to a lower or higher potential with respect to minimal or maximal input voltages. This may, in one embodiment, be accomplished by the use of a single charge pump.

1. An integrated circuit comprising:
a transmission gate; and
at least one charge pump,
wherein the transmission gate comprises at least one metal-oxide-semiconductor (MOS) transistor of a conductivity type,
wherein the at least one MOS transistor comprises a doped bulk well, and
wherein the at least one charge pump is configured to pump the doped bulk well to a first predetermined voltage.

2. The integrated circuit of claim 1, wherein the transmission gate is configured to forward an input voltage when the transmission gate is operated at a first control voltage, and is configured to block the input voltage when the transmission gate is operated at a second control voltage.

3. The integrated circuit of claim 2,
wherein the at least one MOS transistor further comprises a gate terminal, and
wherein the at least one charge pump is further configured to pump the gate terminal to a second predetermined voltage.

4. The integrated circuit of claim 2, wherein the first predetermined voltage is, depending on the conductivity type, either at least a diode drop voltage smaller than the first control voltage or at least a diode drop voltage larger than the second control voltage.

5. The integrated circuit of claim 3, wherein the second predetermined voltage is, depending on the conductivity type, either smaller than a minimal input voltage or larger than a maximal input voltage.

6. A multi-channel multiplexer comprising an integrated circuit, the integrated circuit comprising:
a transmission gate; and
at least one charge pump,
wherein the transmission gate comprises at least one metal-oxide-semiconductor (MOS) transistor of a conductivity type,
wherein the at least one MOS transistor comprises a doped bulk well, and
wherein the at least one charge pump is configured to pump the doped bulk well to a first predetermined voltage.

7. A multi-channel multiplexer, comprising:
a plurality of double transmission gates; and
at least one charge pump,
wherein each of the double transmission gates comprises at least two metal-oxide-semiconductor (MOS) transistors of a first conductivity type,
wherein the two MOS transistors of the first conductivity type share a common doped bulk well of a second conductivity type, and
wherein the at least one charge pump is configured to pump the doped bulk well to a predetermined voltage.

8. The multi-channel multiplexer of claim 7, wherein at least one of the plurality of double transmission gates is
configured to forward an input voltage when the double transmission gate is operated at a first control voltage, and
configured to block the input voltage when the double transmission gate is operated at a second control voltage,
wherein the first control voltage is different from the second control voltage.

9. The multi-channel multiplexer of claim 8,
wherein the at least one charge pump is configured to provide a voltage that is at least a diode drop voltage smaller than the lower of the first control voltage or the second control voltage, and/or a voltage that is at least a diode drop voltage larger than the higher of the first control voltage or the second control voltage.

10. The multi-channel multiplexer of claim 7, further comprising:
a plurality of transistors each configured to control a corresponding transistor voltage at at least one of the MOS transistors of the first conductivity type of a corresponding double transmission gate.

11. The multi-channel multiplexer of claim 10, wherein at least one transistor of the plurality of transistors has a common connection point with the at least one MOS transistor of the first conductivity type.

12. The multi-channel multiplexer of claim 10, wherein at least one transistor of the plurality of transistors is connected to a source terminal of a first of the at least two MOS transistors of the first conductivity type of one of the plurality of double transmission gates, and is connected to a drain terminal of a second of the at least two MOS transistors of the first conductivity type of the one of the plurality of double transmission gates.

13. The multi-channel multiplexer of claim 10, wherein the transistor voltage is larger than or equal to the first control voltage and/or smaller than or equal to the second control voltage.

14. A method for operating a plurality of input channels of a multi-input-channel system, wherein each of the plurality of input channels comprises at least one doped bulk well of a conductivity type, the method comprising:
blocking each input channel of a selection of the plurality of input channels by at least one corresponding control voltage, and
bringing each of the at least one doped bulk well of each of the input channels of the selection of the plurality of input channels to an at least one corresponding predetermined voltage,
wherein the at least one corresponding predetermined voltage is, depending on the conductivity type, either smaller than the corresponding control voltage, or larger than the corresponding control voltage.

15. The method of claim 14, wherein the method further comprises:
determining the at least one corresponding predetermined voltage based on at least one characteristic of at least one metal-oxide-semiconductor (MOS) transistor comprised by a doped bulk well of a corresponding input channel.

16. The method of claim 14, wherein bringing each of the at least one doped bulk well to the at least one corresponding predetermined voltage comprises pumping a voltage by a charge pump.

17. The method of claim 16, wherein the method further comprises:
controlling a corresponding transistor voltage at at least one of a source terminal and/or a drain terminal of a at least one MOS transistor comprised by a doped bulk well of a corresponding input channel.

18. The method of claim 17, wherein the controlling of the corresponding transistor voltage is based on at least one characteristic of the at least one MOS transistor comprised by the doped bulk well of the corresponding input channel.

19. The method of claim 14, wherein the method further comprises:
blocking all except one input channel, and
forwarding an input voltage received at the one input channel to an output channel.

20. The method of claim 15, wherein blocking each input channel of the selection of input channels by the at least one corresponding control voltage further comprises:
applying the at least one corresponding control voltage to a gate terminal of the at least one MOS transistor of the corresponding input channel.
